(19) United States
(12) Patent Application Publication
(10) Pub. No.: US 2018/0164448 A1
(43) Pub. Date: Jun. 14, 2018

(54) RADIATON DETECTOR

(71) Applicant: TOSHIBA ELECTRON TUBES & DEVICES CO., LTD., Otawara-shi (JP)

(72) Inventor: Hiroshi ONIHASHI, Nasushiobara (JP)

(73) Assignee: TOSHIBA ELECTRON TUBES & DEVICES CO., LTD., Otawara-shi (JP)

(21) Appl. No.: 15/892,048

(22) Filed: Feb. 8, 2018

Related U.S. Application Data
(63) Continuation of application No. PCT/JP2017/025684, filed on Jul. 14, 2017.

(30) Foreign Application Priority Data
Oct. 3, 2016 (JP) 2016-195333

(51) Int. Cl. G01T 1/24; G01T 1/20; G01T 1/208; G01T 1/29

(52) U.S. Cl. CPC G01T 1/247; G01T 1/2928; G01T 1/208; G01T 1/2018

(57) ABSTRACT

According to one embodiment, a radiation detector includes an array substrate including a plurality of control lines, a plurality of data lines, and a plurality of detection parts, the detection parts detecting radiation directly or in cooperation with a scintillator, a signal detection circuit reading out an image data signal from the plurality of detection parts, a noise detection circuit detecting a noise, a plurality of first wirings, one end portion of each of the first wirings being electrically connected to the data lines, other end portion of each of the first wirings being electrically connected to the signal detection circuit, and a second wiring, one end portion of the second wiring being not electrically connected to the data lines being electrically connected to the plurality of detection parts.

### CROSS-REFERENCE TO RELATED APPLICATIONS

This application is based upon and claims the benefit of priority from Japanese Patent Application No. 2016-195333, filed on Oct. 3, 2016, and the PCT Patent Application PCT/JP2017/025684, filed on Jul. 14, 2017; the entire contents of which are incorporated herein by reference.

### FIELD

The embodiments of the invention relate to a radiation detector.

### BACKGROUND

There is an X-ray detector as one example of a radiation detector. The X-ray detector includes a scintillator converting an incident X-ray to fluorescence, an array substrate provided with a plurality of photoelectric conversion parts (called pixel or the like) converting fluorescence to a signal charge, and a signal processing part provided with a control circuit and a signal detection circuit or the like. The array substrate is provided with a plurality of control lines and a plurality of data lines electrically connected to the plurality of photoelectric conversion parts. In general, the plurality of data lines and the signal detection circuit are electrically and mechanically connected via a flexible printed board. The signal detection circuit may be mounted on the flexible printed board.

In general, the X-ray detector reads out the signal charge as follows. First, the detector recognizes X-ray incidence from a signal input externally. Next, the detector reads out the stored signal charge by turning on a thin film transistor of the photoelectric conversion part performing reading after the passage of a pre-determined time (a time necessary for storing the signal charge).

Here, if a vibration is applied to the X-ray detector when reading out the signal charge, the flexible printed board is shaken by the vibration and an induced noise may occur. If the induced noise occurs, the induced noise overlaps the read out signal charge, and quality of an image is deteriorated.

In such a case, if an accelerometer is provided on the X-ray detector, the application of the vibration to the X-ray detector can be detected by the accelerometer. However, in this way, a new problem of complication of the configuration of the X-ray detector occurs.

Then, the development of a radiation detector capable of detecting the occurrence of the noise by the simple configuration has been desired.

### BRIEF DESCRIPTION OF THE DRAWINGS

FIG. 1 is a schematic perspective view for illustrating an X-ray detector;

FIG. 2 is a block diagram of the X-ray detector;

FIG. 3 is a circuit diagram of an array substrate;

FIG. 4 is a photograph for illustrating an image data signal and a noise signal;

FIG. 5 is a graph view for illustrating a waveform of the noise signal;

FIGS. 6A and 6B are schematic views for illustrating an end portion of a wiring on a side of the array substrate, and mechanical connection to the array substrate; and

FIGS. 7A and 7B are schematic views for illustrating an end portion of a wiring on a side of the array substrate, and mechanical connection to the array substrate.

### DETAILED DESCRIPTION

According to one embodiment, a radiation detector includes an array substrate including a plurality of control lines extending in a first direction, a plurality of data lines extending in a second direction crossing the first direction, and a plurality of detection parts provided in each of a plurality of regions drawn by the plurality of control lines and the plurality of the data lines, electrically connected to the corresponding control line and the corresponding data line, and detecting radiation directly or in cooperation with a scintillator, a signal detection circuit reading out an image data signal from the plurality of detection parts, a noise detection circuit detecting a noise, a plurality of first wirings, one end portion of each of the first wirings being electrically connected to the data lines, other end portion of each of the first wirings being electrically connected to the signal detection circuit, and a second wiring, one end portion of the second wiring being not electrically connected to the data lines being electrically connected to the plurality of detection parts.

Embodiments will be illustrated with reference to the accompanying drawings. In the drawings, similar components are marked with like reference numerals, and the detailed description is omitted as appropriate.

The radiation detector according to the embodiment can be applied to various radiations such as a γ-ray other than an X-ray. Here, the case of the X-ray as a representative of radiations is described as one example. Therefore, the detector can be also applied to other radiation by replacing “X-ray” of the following embodiments with “other radiation”.

The X-ray detector 1 illustrated below is an X-ray plane sensor detecting an X-ray image which is a radiation image. The X-ray plane sensor includes a direct conversion method and an indirect conversion method broadly.

The direct conversion method is a method that a photoconductive charge (signal charge) generated inside a photoconductive film by the X-ray incidence is introduced directly to a storing capacitor for charge storage.

The indirect conversion method is a method that the X-ray is converted to fluorescence (visible light) by a scintillator, the fluorescence is converted to the signal charge by a photoelectric conversion element such as a photodiode, and the signal charge is introduced to the storing capacitor.

In the following, the X-ray detector 1 of the indirect conversion method is illustrated as one example, however the invention can be applied to the X-ray detector of the indirect conversion method as well.

That is, the X-ray detector may be a detection part that detects the X-ray directly or in cooperation with the scintillator.

The X-ray detector 1 can be used for, for example, general medical application or the like, and the application is not limited.

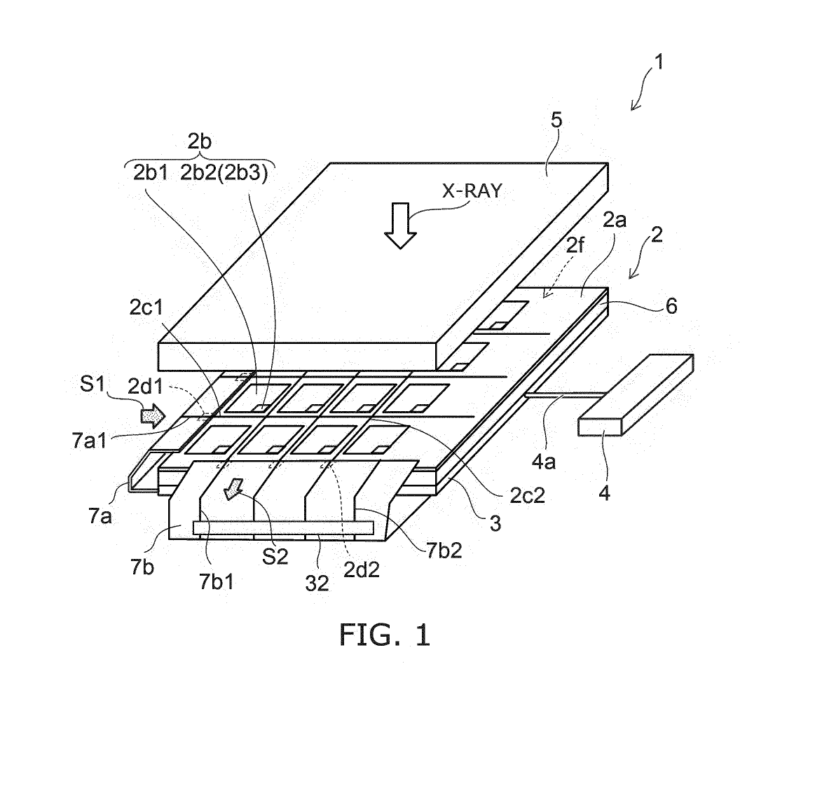

FIG. 1 is a schematic view for illustrating the X-ray detector 1.

In FIG. 1, a bias line 2c3 or the like is omitted.

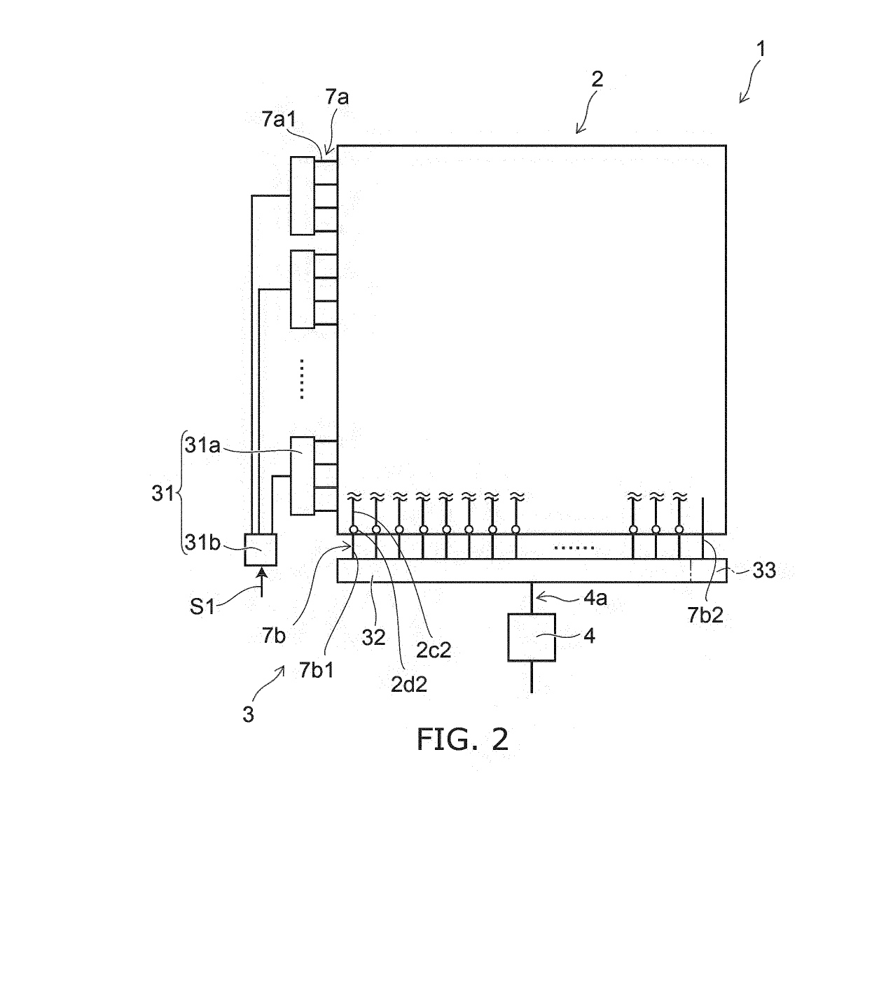

FIG. 2 is a block diagram of the X-ray detector 1.

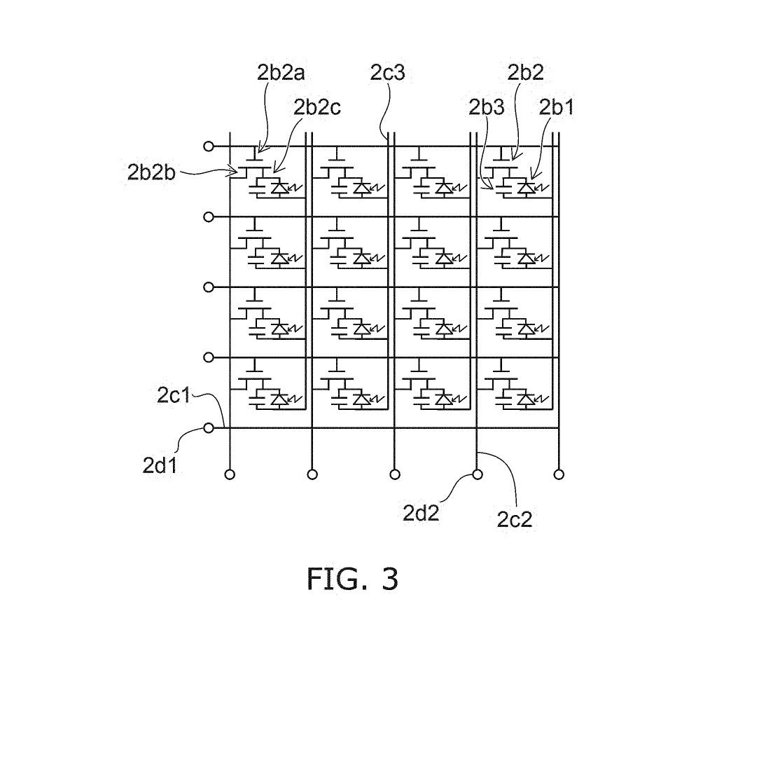

FIG. 3 is a circuit diagram of an array substrate 2.

As shown in FIG. 1 to FIG. 3, the X-ray detector 1 is provided with the array substrate 2, a signal processing part 3, an image processing part 4, a scintillator 5, a support plate 6, and flexible printed boards 7a, 7b.

The array substrate 2 converts the fluorescence (visible light) converted from the X-ray by the scintillator 5 to an electric signal.

The array substrate 2 includes a substrate 2a, a photoelectric conversion part 2b, a control line (or gate line) 2c1, a data line (or signal line) 2c2, and a bias line 2c3.

The number and arrangement or the like of the photoelectric conversion part 2b, the control line 2c1, the data line 2c2, and the bias line 2c3 are not limited to the illustration.

The substrate 2a is plate-shaped, and is formed from a light transmissive material such as a non-alkali glass.

The photoelectric conversion part 2b is provided in a plurality on a surface of the substrate 2a.

The photoelectric conversion part 2b is rectangular flat plate-shaped, and is provided in a region drawn by the control line 2c1 and the data line 2c2. The plurality of photoelectric conversion parts 2b are arranged in a matrix.

One photoelectric conversion part 2b corresponds to one picture element (pixel).

Each of the plurality of photoelectric conversion parts 2b is provided with a photoelectric conversion element 2b1, and a thin film transistor (TFT) 2b2 which is a switching element.

As shown in FIG. 3, a storing capacitor 2b3 which stores the signal charge converted by the photoelectric conversion element 2b1 can be provided. The storing capacitor 2b3 is, for example, rectangular flat plate-shaped, and can be provided under the respective thin film transistor 2b2. However, depending on a capacity of the photoelectric conversion element 2b1, the photoelectric conversion element 2b1 can serve as the storing capacitor 2b3.

The photoelectric conversion element 2b1 can be, for example, a photodiode or the like.

The thin film transistor 2b2 performs switching of storing and release of a charge generated by incidence of the fluorescence to the photoelectric conversion element 2b1. The thin film transistor 2b2 includes a gate electrode 2b2a, a source electrode 2b2b and a drain electrode 2b2c. The gate electrode 2b2a of the thin film transistor 2b2 is electrically connected to the corresponding control line 2c1. The source electrode 2b2b of the thin film transistor 2b2 is electrically connected to the corresponding data line 2c2. The drain electrode 2b2c of the thin film transistor 2b2 is electrically connected to the corresponding photoelectric conversion element 2b1 and the storing capacitor 2b3. The storing capacitor 2b3 and the anode side of the photoelectric conversion element 2b1 are electrically connected to the corresponding bias line 2c3 (see FIG. 3).

The control line 2c1 is provided in a plurality to be parallel to each other with a prescribed spacing. The control lines 2c1 extend, for example, in a row direction (corresponding to one example of a first direction). One control line 2c1 is electrically connected to one of a plurality of wiring pads 2d1 provided near the periphery of the substrate 2a.

The data line 2c2 is provided in a plurality to be parallel to each other with a prescribed spacing. The data lines 2c2 extend, for example, in a column direction (corresponding to one example of a second direction) orthogonal to the row direction. One data line 2c2 is electrically connected to one of a plurality of wiring pads 2d2 provided near the periphery of the substrate 2a.

As shown in FIG. 3, the bias line 2c3 is provided to be parallel to the data line 2c2 between the data line 2c2 and the data line 2c2.

The bias line 2c3 is electrically connected to a bias power source not shown. The bias power source not shown can be provided, for example, on the signal processing part 3 or the like.

The bias line 2c3 is not always necessary, and may be provided as necessary. In the case where the bias line 2c3 is not provided, the storing capacitor 2b3 and the anode side of the photoelectric conversion element 2b1 are electrically connected to the ground in place of the bias line 2c3.

The control line 2c1, the data line 2c2, and the bias line 2c3 can be formed based on, for example, a low resistance metal such as aluminum and chromium or the like.

A protection layer 2f covers the photoelectric conversion part 2b, the control line 2c1, the data line 2c2, and the bias line 2c3. The protection layer 2f includes, for example, at least one of an oxide insulating material, a nitride insulating material, oxynitride insulating material, and a resin material.

The signal processing part 3 is provided on an opposite side to a side of the scintillator 5 of the array substrate 2.

The signal processing part 3 is provided with a control circuit 31, a signal detection circuit 32, and a noise detection circuit 33.

As shown in FIG. 1, the signal detection circuit 32 can be provided on the flexible printed board 7b as well.

The control circuit 31 switches between an on state and an off state of the thin film transistor 2b2.

As shown in FIG. 2, the control circuit 31 includes a plurality of gate drivers 31a and a column selection circuit 31b.

A control signal S1 is input from the image processing part 4 or the like to the column selection circuit 31b. The column selection circuit 31 inputs the control signal S1 to the corresponding gate driver 31a in accordance with a scanning direction of the X-ray image.

The gate driver 31a inputs the control signal S1 to the corresponding control line 2c1.

For example, the control circuit 31 inputs the control signal S1 sequentially to every control line 2c1 via the flexible printed board 7a and the control line 2c1. The thin film transistor 2b2 is turned on by the control signal S1 inputted to the control line 2c1, and the signal charge (image data signal S2) from the photoelectric conversion element 2b1 can be received.

The signal detection circuit 32 reads out the signal charge (image data signal S2) from the storing capacitor 2b3 via a wiring 7b1 (corresponding to one example of first wirings) of the flexible printed board 7b in accordance with a sampling signal from the image processing part 4 when the thin film transistor 2b2 is in the on state.

The noise detection circuit 33 detects a dielectric noise generated in the wiring 7b2 (corresponding to one example of second wirings) of the flexible printed board 7b when the thin film transistor 2b2 is in the on state. That is, the noise detection circuit 33 detects the noise signal flowing in the wiring 7b2. The detail of detection of the noise signal is described later.

Both of the signal detection circuit 32 and the noise detection circuit 33 are circuits detecting the signal. Therefore, the configuration of the noise detection circuit 33 can be similar to the configuration of the signal detection circuit 32. For example, as shown in FIG. 2, a portion of a plurality of channels provided in the signal detection circuit 32 can be the noise detection circuit 33. In this way, space saving and reduction of manufacturing cost can be made.

The image processing part 4 is electrically connected to the signal processing part 3 via a wiring 4a. The image processing part 4 may be integrated with the signal processing part 3. The image processing part 4 configures the X-ray image on the basis of the read image data signal S2.

The scintillator 5 is provided on a plurality of photoelectric conversion elements 2b1, and converts the incident X-ray to fluorescence. The scintillator 5 is provided to cover a region (effective pixel region) where a plurality of photoelectric conversion parts on the substrate 2a are provided. The scintillator 5 can be formed based on, for example, cesium iodide (CsI):thallium (TI), or sodium iodide (NaI):thallium (TI) or the like. In this case, if the scintillator 5 is formed by using a vacuum deposition method or the like, the scintillator 5 made of a plurality of columnar crystal aggregations is formed.

The scintillator 5 can be also formed by using, for example, oxysulfide gadolinium (Gd₂O₂S) or the like. In this case, the quadrangular prismatic scintillator 5 can be provided every the plurality of photoelectric conversion parts 2b.

Other, in order to increase a utilization efficiency of the fluorescence and improve sensitivity characteristics, a reflection layer not shown can be provided so as to cover a surface side (incident surface side of X-ray) of the scintillator 5.

In order to suppress deterioration of the characteristics of the scintillator 5 and the characteristics of the reflection layer not shown by water vapor included in air, a moisture proof body not shown covering the scintillator 5 and the reflection layer not shown can be provided.

The support plate 6 is plate-shaped. The support plate 6 is fixed to inside a housing not shown. The array substrate 2 and the scintillator 5 are provided on a surface of the support plate 6 on an X-ray incidence side. The signal processing part 3 is provided on a surface of the support plater 6 on an opposite side to the X-ray incidence side. A material of the support plate 6 can be, for example, a light metal such as an aluminum alloy or the like, a resin such as a carbon fiber reinforced plastic or the like.

The flexible printed board 7a is electrically connected to the plurality of control lines 2c1 and the control circuit 31. One of the plurality of wirings 7a1 provided on the flexible printed board 7a is electrically connected to one of the plurality of wiring pads 2d1. Other end of the plurality of wirings 7a1 provided on the flexible printed board 7a is electrically connected to the gate driver 31a.

The flexible printed board 7b is electrically connected to the plurality of data lines 2c2 and the signal detection circuit 32. One of the plurality of wirings 7b1 provided on the flexible printed board 7b is electrically connected to one of the plurality of wiring pads 2d2. That is, one end portion of each of the plurality of wirings 7b1 is electrically connected to the data line 2c2. Other end portion of each of the plurality of wirings 7b1 is electrically connected to the signal detection circuit 32.

The wiring 7b2 is provided on the flexible printed board 7b. The wiring 7b2 may be provided in a plurality. An end portion of the wiring 7b2 on a side of the substrate 2 is not electrically connected to the data line 2c2 electrically connected to the plurality of photoelectric conversion parts 2b. Other end portion of the wiring 7b2 is electrically connected to the noise detection circuit 33.

Next, the detection of the noise signal will be described.

In the X-ray detector 1, the X-ray image is configured as follows.

First, the thin film transistors 2b2 are sequentially turned on by the control circuit 31. The thin film transistors 2b2 is turned on, and thus a certain amount of charges are stored in the storing capacitance 2b3 via the bias line 2c3. Next, the thin film transistors 2b2 are turned off. If the X-ray is irradiated, the X-ray is converted to the fluorescence by the scintillator 5. If the fluorescence is incident on the photoelectric conversion element 2b1, a charge (electron or hole) is generated by a photoelectric effect, the generated electron and the stored charge (heterogeneous charge) couple, and the stored charges decrease. Next, the control circuit 31 makes the thin film transistors 2b2 on state sequentially. The signal detection circuit 32 reads out the reduced charges (image data signal S2) stored in the respective storing capacitors 2b3 via the data line 2c2 in accordance with the sampling signal.

The image processing part 4 receives the read image data signal S2, amplifies sequentially the received image data signal S2, and converts the amplified image data signal S2 (analog signal) to a digital signal. The image processing part 4 configures the X-ray image on the basis of the image data signal S2 converted to the digital signal. The data of the configured X-ray image are output toward an external equipment from the image processing part 4.

As described previously, the plurality of data lines 2c2 and the signal detection circuit 32 are electrically connected via the flexible printed board 7b. In this case, a vibration is applied to the X-ray detector 1, the flexible printed board 7b vibrates, and the positional relationship between the wiring 7b1 and other component (for example, substrate 2a) may change. If the positional relationship between the wiring 7b1 and other component changes, a coupling capacitance between the wiring 7b1 and the ground changes, and an induced noise occurs. The induced noise occurs when reading out the image data signal S2 from the signal detection circuit 32, the induced noise overlaps the image data signal S2, and quality of the image is deteriorated. In this case, it is difficult to separate only the image data signal S2 from the image data signal S2 overlapped with the induced noise. It is extremely difficult to judge whether the image data signal is the image data signal S2 overlapped with the induced noise or not, too. In this case, if the accelerometer is provided on the X-ray detector 1 and the application of the vibration to the X-ray detector 1 is detected by the accelerometer, the occurrence of the induced noise can be detected indirectly. However, in this way, the configuration of the X-ray detector 1 is complicated. It is impossible to detect the occurrence of the noise directly by the accelerometer.

Then, in the X-ray detector 1 according to the embodiment, the wiring 7b2 is provided on the flexible printed board 7b.

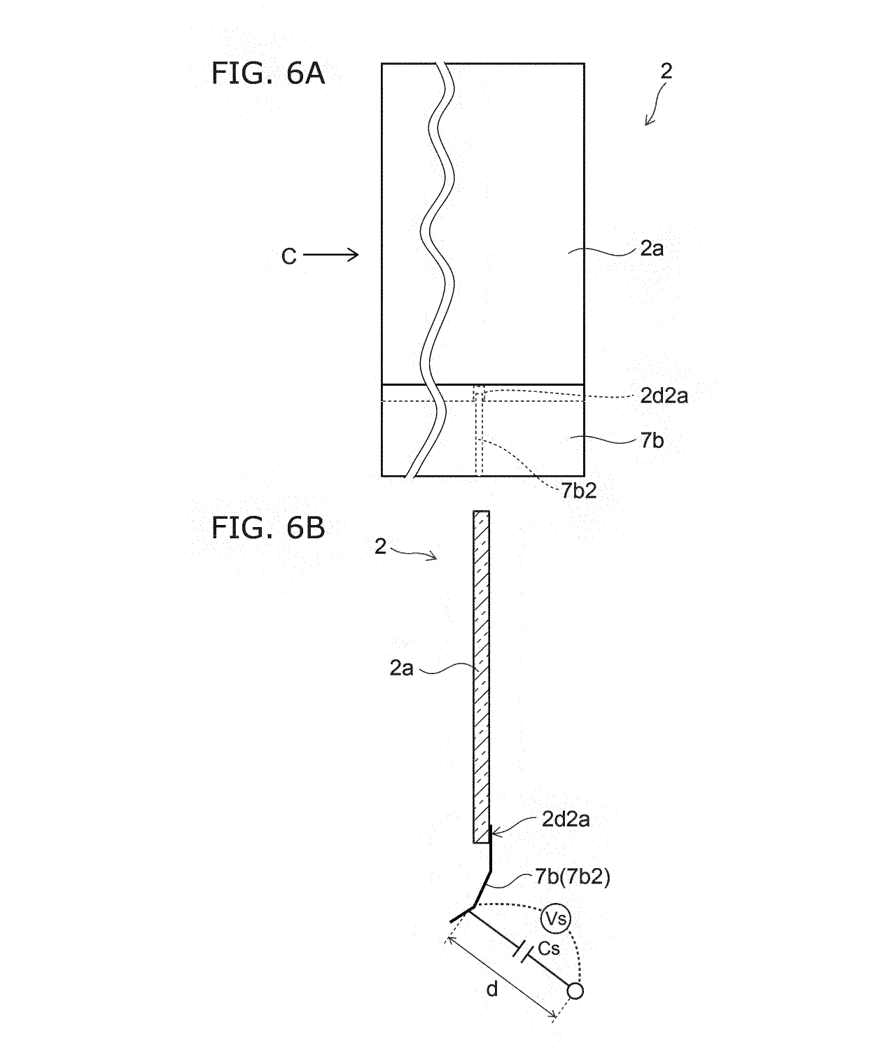

Here, if an induced charge occurring between the wiring 7b2 (including wiring pad 2d2a) and the other component is Qs, a parasitic capacitance is Cs, and a potential difference is Vs, there is a relationship of Qs=Cs·Vs. Furthermore, if a dielectric constant between the wiring 7b2 and the other component is E, an effective area of a metal portion of the wiring 7b2 is S, and a distance between the wiring 7b2 and the other component is d, Cs can be expressed by Cs=ε·S/d (for example, see FIG. 6B). Therefore, if the flexible printed board 7b vibrates, the positional relationship between the wiring 7b2 and the other component changes (±Δd), and the induced noise ΔQs=ε·S·Vs/(d±Δd) due to the induced charge occurs.

Different from the wiring 7b1, the end portion of the wiring 7b2 on a side of the array substrate 2 is not electrically connected to the data line 2v2 electrically connected to the plurality of photoelectric conversion parts 2b. Therefore, only the noise signal due to the induced noise flows in the wiring 7b2.

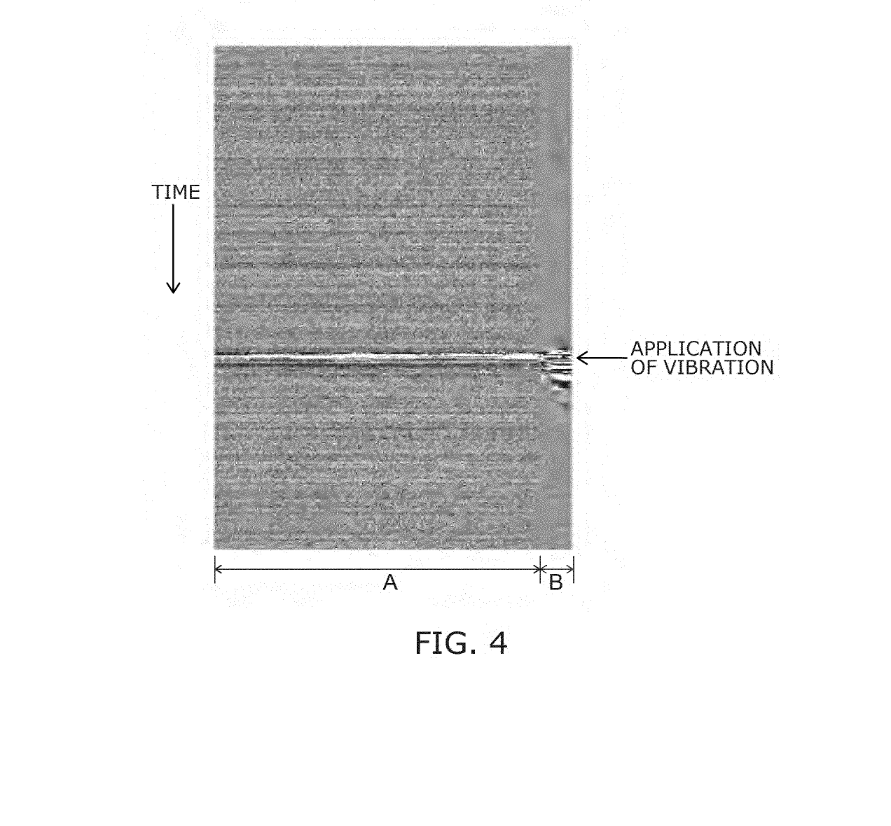

FIG. 4 is a photograph for illustrating the image data signal S2 and the noise signal.

The signal in a region A in FIG. 4 represents the signal flowing in the plurality of wirings 7b1.

The signal in a region B in FIG. 4 represents the noise signal flowing in the wiring 7b2.

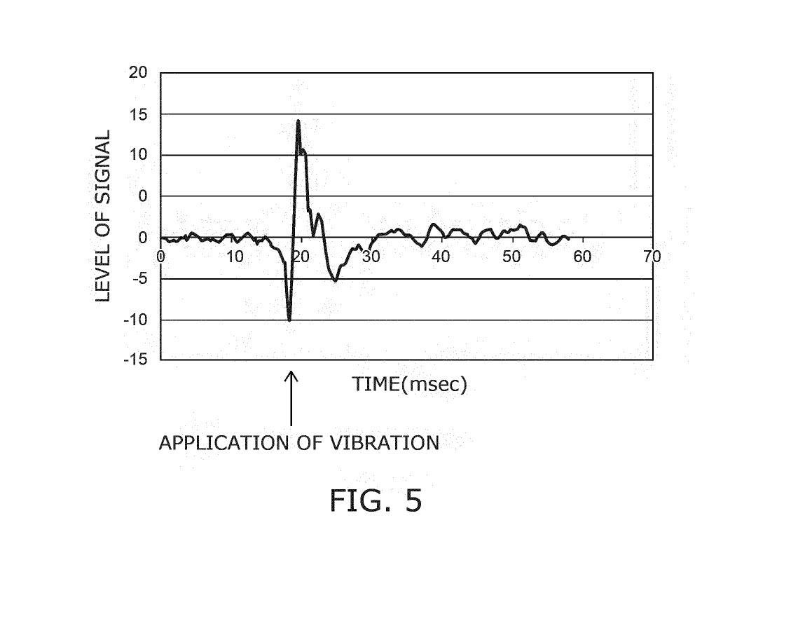

FIG. 5 is a graph view for illustrating a waveform of the noise signal.

As shown in FIG. 4, the vibration is applied to the X-ray detector 1, the flexible printed board 7b vibrates and the induced noise occurs in the plurality of wirings 7b1 and the wiring 7b2.

As seen from FIG. 4, the noise signal which occurs in the plurality of wirings 7b1 overlaps the image data signal S2. Therefore, the quality of the image is deteriorated

On the other hand, as seen from FIG. 4 and FIG. 5, the noise signal which occurs in the wiring 7b2 does not overlap the image data signal S2. Therefore, the noise signal flowing in the wiring 7b2 can be detected.

The detection of the noise signal can be performed by the noise signal detection circuit 33. In this case, if a level of the signal flowing in the wiring 7b2 exceeds a predetermined value as shown in FIG. 5, the noise detection circuit 33 can judge the occurrence of the noise. That is, the noise detection circuit 33 detects the noise signal flowing in the wiring 7b2 of the flexible printed board 7b when the thin film transistor 2b2 is in the on state. When the noise signal is detected, the noise detection circuit 33 transmits information about the noise signal to the image processing part 4.

The image processing part 4 performs, for example, at least one of stop of reading of the image data signal S2, discarding of one scree worth of the image data signal S2 including the noise signal, correction of the image data signal S2 including the noise signal, and output of alarm on the basis of the information about the noise signal.

In the correction of the image data signal S2, for example, it is possible to discard a portion including the noise signal and form data of the discarded portion on the basis of the image data signal S2.

In the case of outputting the alarm, it is possible that the stop of the reading of the image data signal S2 previously described is performed until the noise signal becomes not more than the predetermined value. In this way, the system without influence due to the vibration can be constructed.

In the above, the case where the induced noise due to the vibration occurs in the wiring 7b2 is illustrated. However, since the wiring 7b2 functions also as an antenna, also in the case where an external electromagnetic induction noise is applied to the X-ray detector 1, the induced noise occurs in the wiring 7b2. Therefore, the electromagnetic induction noise can be also detected by providing the wiring 7b2.

If the X-ray is incident on the X-ray detector 1, an after image may occur. Therefore, in order to remove the occurred after image, an image correction processing using offset data may be performed. The offset data are image data output from the X-ray detector 1 when the X-ray is not incident, and are called as dark image or dark or the like. In order to remove the after image, the offset data are subtracted from the image data signal S2.

If the vibration is applied to the X-ray detector 1 when obtaining the offset data, the noise signal overlaps the offset data. If the noise signal overlaps the offset data, the quality of the offset data is deteriorated.

Therefore, it is favorable to detect the noise signal also when obtaining the offset data.

In the case where the noise signal is detected when obtaining the offset data, the similar processing to the case of the image data signal S2 previously described can be performed.

That is, the noise detection circuit 33 detects the noise signal flowing in the wiring 7b2 of the flexible printed board 7b when the thin film transistor 2b2 is in the on state. When the noise signal is detected, the noise detection circuit 33 transmits the information about the noise signal to the image processing part 4. The image processing part 4 performs, for example, at least one of stop of reading of the offset data, discarding the offset data including the noise signal, correction of the offset data including the noise signal, and output of alarm on the basis of the information about the noise signal. In the case of outputting the alarm, it is possible that the stop of the reading of the offset data previously described is performed until the noise signal becomes not more than the predetermined value. In this way, it is possible to obtain the offset data without mix of the induced noise due to the vibration.

The X-ray detector 1 may be provided with a circuit detecting the X-ray incidence. If the vibration is applied to the X-ray detector 1, the induced noise due to the vibration occurs, and there is a fear that incorrect detection signal is output from the circuit detecting the X-ray incidence. Therefore, it is favorable to detect the noise signal also when detecting the X-ray incidence.

In the case where the noise signal is detected when detecting the X-ray incidence, the similar processing to the case of the image data signal S2 previously described can be performed.

That is, the noise detection circuit 33 detects the noise signal flowing in the wiring 7b2 of the flexible printed board 7b when the thin film transistor 2b2 is in the on state. When the noise signal is detected, the noise detection circuit 33 transmits the information about the noise signal to the image processing part 4. The image processing part 4 performs, for example, at least one of stop of outputting the detection signal from the circuit detecting the X-ray incidence, discarding the detection signal from the circuit detecting the X-ray incidence, and output of alarm on the basis of the information about the noise signal. In the case of outputting the alarm, it is possible that the stop of the output of the detection signal from the circuit detecting the X-ray incidence previously described is performed until the noise signal becomes not more than the predetermined value. In this way, it is possible to suppress start of imaging due to the incorrect detection signal.

Next, the end portion of the wiring 7b2 on a side of the array substrate 2 will be described.

As described previously, the end portion of the wiring 7b2 on a side of the array substrate 2 is not electrically connected to the data line 2c2 electrically connected to the plurality of photoelectric conversion parts 2b.

In this case, the end portion of the wiring 7b2 on a side of the array substrate 2 is not necessary to be mechanically connected to the array substrate 2. That is, the end portion of the wiring 7b2 on a side of the array substrate 2 can be a free end. Even if the end portion of the wiring 7b2 on a side of the array substrate 2 is not mechanically connected to the array substrate 2, if the flexible printed board 7b vibrates, the noise signal can be detected.

However, since the flexible printed board 7b is not connected to the housing of the X-ray detector 1, the vibration applied to the housing of the X-ray detector 1 may be also difficult to be transmitted to the flexible printed board 7b. In this case, if the vibration of the flexible printed board 7b becomes small, there is a fear that the noise signal is hard to be detected.

On the other hand, the array substrate 2 is fixed to the housing of the X-ray detector 1 via the support plate 6. Therefore, the vibration transmitted to the housing of the X-ray detector 1 is easy to be transmitted to the array substrate 2. In this case, if the end portion of the wiring 7b2 on a side of the array substrate 2 is mechanically connected to the array substrate 2, the vibration of the flexible printed board 7b can be large, and thus the noise signal is easy to be detected.

FIGS. 6A and 6B are schematic views for illustrating the mechanical connection between the end portion of the wiring 7b2 on a side of the array substrate 2 and the array substrate 2.

FIG. 6B is a view of the array substrate 2 seen in a C-direction in FIG. 6A.

As shown in FIGS. 6A, 6B, it is possible that the wiring pad 2d2a is provided near the periphery of the substrate 2a, and the end portion of the wiring 7b2 on a side of the array substrate 2 is soldered to the wiring pad 2d2a. The wiring pad 2d2a can be similar to the wiring pads 2d2. Or, at least one of the end portion of the wiring 7b2 on a side of the array substrate 2 and the end portion of the flexible printed board 7b on a side of the array substrate 2 may be fixed to the array substrate 2 with an adhesive or the like.

That is, it suffices that at least one of the end portion of the wiring 7b2 on a side of the array substrate 2 and the end portion of the flexible printed board 7b on a side of the array substrate 2 is mechanically connected to the array substrate 2. In this way, the vibration applied to the housing of the X-ray detector 1 can be transmitted efficiently to the wiring 7b2 via the array substrate 2. Therefore, the detection accuracy of the noise signal can be improved.

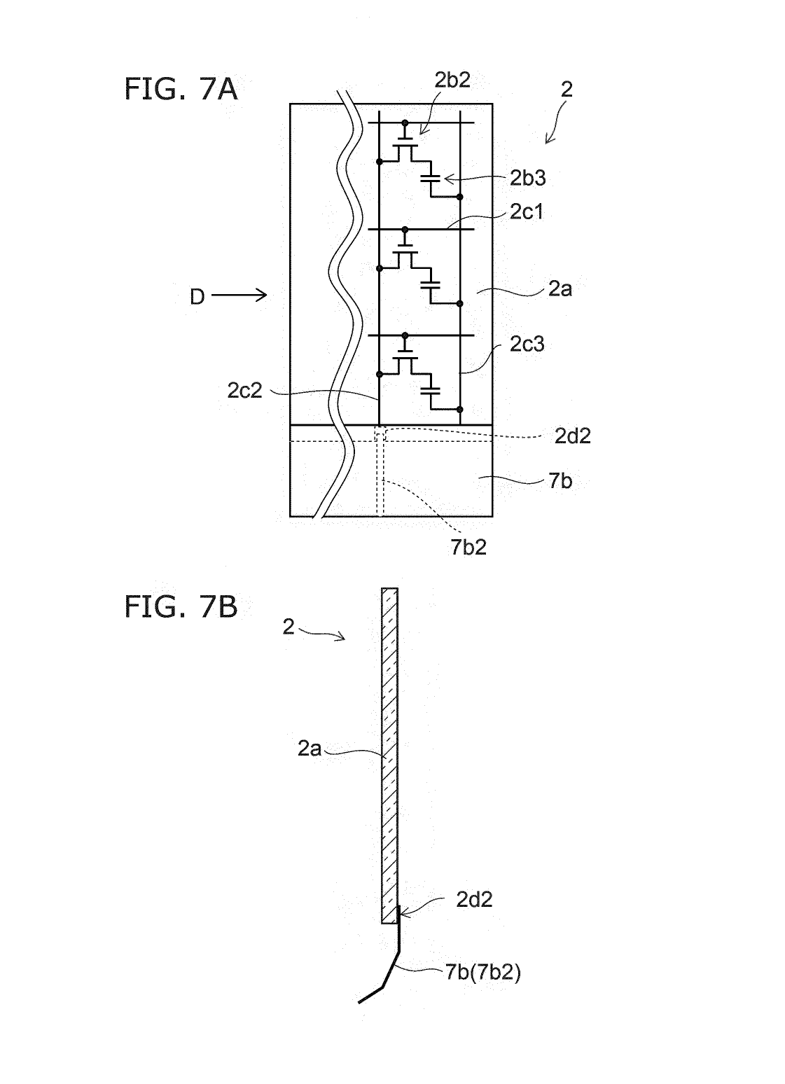

FIGS. 7A and 7B are schematic views for illustrating, the mechanical connection between the end portion of the wiring 7b2 on a side of the array substrate 2 and the array substrate 2.

FIG. 7B is a view of the array substrate 2 seen in a D-direction in FIG. 7A.

As shown in FIG. 7A, it can be configured that the photoelectric conversion element 2b1 is not electrically connected to one of the plurality of data lines 2c2. For example, when forming the plurality of photoelectric conversion parts 2b to be arranged in a matrix, it can be configured that the photoelectric conversion element 2b1 is not formed in the plurality of photoelectric conversion parts 2b electrically connected to one data line 2c2. If the photoelectric conversion element 2b1 is not formed, the charge stored in the storing capacitance 2b3 becomes generally constant. Therefore, the thin film transistor 2b2 is turned on, and thus a current flowing in the data line 2c2 becomes generally constant. If the current flowing in the data line 2c2 becomes generally constant, even if this current overlaps the noise signal, the noise signal can be detected.

It can be also configured that the photoelectric conversion part 2b is not electrically connected to one of the plurality of data lines 2c2.

The end portion of the wiring 7b1 on a side of the array substrate 2 is electrically and mechanically connected to the data line 2c2 not electrically connected to the photoelectric conversion element 2b1 or the photoelectric conversion part 2b.

For example, the end portion of the wiring 7b2 on a side of the array substrate 2 can be soldered to the wiring pad 2d2.

At least one of the end portion of the wiring 7b2 on a side of the array substrate 2 and the end portion of the flexible printed board 7b on a side of the array substrate 2 may be fixed to the array substrate 2 with an adhesive or the like.

That is, it suffices that at least one of the end portion of the wiring 7b2 on a side of the array substrate 2 and the end portion of the flexible printed board 7b on a side of the array substrate 2 is mechanically connected to the array substrate 2. In this way, the vibration applied to the housing of the X-ray detector 1 can be efficiently transmitted to the wiring 7b2 via the array substrate 2. Therefore, the detection accuracy of the noise signal can be improved.

When forming the plurality of photoelectric conversion parts 2b to be arranged in a matrix, it is only necessary not to form the photoelectric conversion element 2b1 in a portion of photoelectric conversion parts 2b, and thus the simplification of the manufacturing process can be made.

In the above, the case where the wiring 7b1 and the wiring 7b2 are provided on the flexible printed board 7b is illustrated, however it may be configured that the wiring 7b is provided on the flexible printed board 7b and the wiring 7b2 is provided to be separated from the flexible printed board 7b. However, if the wiring 7b2 is provided on the flexible printed board 7b, the vibration applied to the housing of the X-ray detector 1 can be transmitted efficiently to the wiring 7b2. Therefore, the detection accuracy of the noise signal can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A radiation detector comprising:
an array substrate including a plurality of control lines extending in a first direction, a plurality of data lines extending in a second direction crossing the first direction, and a plurality of detection parts provided in each of a plurality of regions drawn by the plurality of control lines and the plurality of the data lines, electrically connected to the corresponding control line and the corresponding data line, and detecting radiation directly or in cooperation with a scintillator;
a signal detection circuit reading out an image data signal from the plurality of detection parts;
a noise detection circuit detecting a noise;
a plurality of first wirings, one end portion of each of the first wirings being electrically connected to the data lines, other end portion of each of the first wirings being electrically connected to the signal detection circuit; and
a second wiring, one end portion of the second wiring being not electrically connected to the data lines being electrically connected to the plurality of detection parts.

2. The radiation detector according to claim 1, wherein the plurality of first wirings and the second wiring are provided on a flexible printed board.

3. The radiation detector according to claim 1, wherein the one end portion of the second wiring is mechanically connected to the array substrate.

4. The radiation detector according to claim 1, wherein
the detection part is not electrically connected to one of the plurality of data lines, and
the one end portion of the second wiring is electrically and mechanically connected to the data lines being not electrically connected to the detection part.

5. The radiation detector according to claim 2, wherein one end portion of the flexible printed board is mechanically connected to the array substrate.

6. The radiation detector according to claim 1, further comprising: an image processing part electrically connected to the signal detection circuit, and configuring a radiation image based on the read image data signal,
the noise detection circuit detecting the noise occurred in the second wiring, and
when the noise being detected, the image processing part performing at least one of stop of reading of the image data signal, discarding of one screen worth of the image data signal including the noise, correction of the image data signal including the noise, and output of alarm.

7. The radiation detector according to claim 6, wherein the stop of reading of the image data signal is performed until the noise becomes not more than a predetermined value.
